(19) United States
(12) Patent Application Publication
(10) Pub. No.: US 2011/0297210 A1
(43) Pub. Date: Dec. 8, 2011

(54) FASTENING BASE AND PACKAGING CONTAINER

(75) Inventors: Atsushi Sato, Kanagawa (JP); Yoshiaki Inoue, Aichi (JP); Mikio Takenaka, Kanagawa (JP)

(73) Assignee: Sony Corporation, Tokyo (JP)

(21) Appl. No.: 13/116,428

(22) Filed: May 26, 2011

(30) Foreign Application Priority Data
Jun. 3, 2010 (JP) 2010-128069

(51) Int. Cl. H01L 31/0203; H01L 31/048

(52) U.S. Cl. 136/251; 136/259

(57) ABSTRACT

Disclosed herein is a fastening base including: an enclosure shaped to fasten a dye sensitized solar cell at a predetermined position in a predetermined posture relative to the enclosure; and a shorting circuit adapted to short the two poles of the dye sensitized solar cell fastened to the enclosure.

### BACKGROUND OF THE INVENTION

1. Field of the Invention

The present invention relates to a fastening base and packaging container, and, more particularly, to a fastening base and packaging container capable of minimizing the deterioration of the power generation characteristic of solar cells.

2. Description of the Related Art

Recent years have seen ever-growing expectations for the widespread use of solar cells, i.e., photoelectric conversion elements adapted to convert sunlight into electric energy, because of their extremely small impact on the global environment made possible by the use of sunlight as a source of energy.

Crystalline silicon-based solar cells using monocrystalline or polycrystalline silicon and amorphous silicon-based solar cells have been primarily used to date.

In contrast, the dye sensitized solar cell proposed by Gratzel et al. in 1991 is drawing attention because this solar cell offers high photoelectric conversion efficiency and, moreover, does not require any large-scale system for manufacture, unlike related-art silicon-based solar cells, and therefore allows for manufacture at low cost (refer, for example, to Nature, 353, p. 737 (1991)).

Incidentally, this dye sensitized solar cell uses an electrolyte layer (liquid or solid) including redox species that is made, for example, of an organic solvent, ionic liquid or gel. Therefore, it is likely that an external circuit connected to the power collection sections of the dye sensitized solar cell will be open-circuited despite the fact that light is irradiated onto the solar cell or that the electrolyte layer of the dye sensitized solar cell may develop polarization in a condition of use in which power is not much consumed (that is, there is an open circuit between the power collection sections). Such polarization may lead to degradation of the power generation characteristic of the dye sensitized solar cell.

More specifically, it is known that electrons accumulate at the interface between the conductive transparent electrode (e.g., FTO or ITO electrode), a semiconductor electrode, and TiO₂ if light is irradiated onto a dye sensitized solar cell and if the external circuit of the same cell is open-circuited.

The dye, the supply source of electrons, is excited not only under the sunlight but also under an indoor fluorescent lamp. As a result, electrons continue to be supplied, thus causing electrons to be accumulated.

If electrons are continuously accumulated at the interface of the conductive transparent electrodes, polarization occurs in the cell. More specifically, electrons leak from the interface between the conductive transparent electrodes and TiO₂, resulting in the reduction of the redox component of the electrolyte layer and causing the imbalance in composition between the oxidants and reductants thereof.

There are three possible reactions for reverse electron transfer, namely, (1) deactivation of the dye from an excited state, (2) electron transfer from TiO₂ to the dye or from TiO₂ to the redox component or (3) electron transfer from the conductive transparent electrodes to the redox component. Of these three possible reactions, the third (3) reaction is the fastest. Therefore, the above reaction is likely to take place with precedence, thus resulting in polarization.

In particular, the larger the area of the dye sensitized solar cell (the larger the current generated by the dye sensitized solar cell), the more electrons are generated per excitation of the dye, and the likelier it is that polarization will take place.

Such polarization is typical of a dye sensitized solar cell using an electrolyte layer (liquid or solid) including redox species that is made, for example, of an organic solvent, ionic liquid or gel. This deterioration mode was not conceivable with related-art silicon-based solar cells (e.g., monocrystalline and amorphous).

Therefore, an approach was devised to reduce the generated polarization and restore the deteriorated power generation characteristic to its original state (refer, for example, to Japanese Patent Laid-Open No. 2008-192441). This approach involves providing a separate electrode in a dye sensitized solar cell to apply a current and applying a reverse current to the dye sensitized solar cell from the electrode using an external power source.

### SUMMARY OF THE INVENTION

In general, however, dye sensitized solar cells are managed alone without being connected to a secondary battery or external circuitry serving as a load circuit before they are used (installed) during manufacture, storage and transport. This may lead to polarization of a dye sensitized solar cell immediately after its manufacture, thus resulting in deterioration of the power generation characteristic prior to its use. That is, a dye sensitized solar cell may not be able to deliver its full power generation characteristic.

The present invention has been made in light of the foregoing, and it is an aim of the present invention to minimize the deterioration of the power generation characteristic of solar cells.

A mode of the present invention is a fastening base that includes an enclosure and shorting circuit. The enclosure is shaped to fasten a dye sensitized solar cell at a predetermined position in a predetermined posture relative to the enclosure. The shorting circuit shorts the two poles of the dye sensitized solar cell fastened to the enclosure.

The fastening base can fasten the plurality of dye sensitized solar cells.

The enclosure can be formed with a conductive material to serve also as the shorting circuit.

The shorting circuit can include a resistor having a predetermined resistance that permits as large a current flow as possible to the extent that the dye sensitized solar cell will not be damaged.

Another mode of the present invention is a packaging container that includes an enclosure and shorting circuit. The enclosure is formed with a light-shielding member and houses a dye sensitized solar cell. The shorting circuit shorts the two poles of the dye sensitized solar cell housed in the enclosure.

The enclosure can have a hollow area to house the dye sensitized solar cell.

The enclosure can be shaped to fasten the dye sensitized solar cell to be housed in the hollow area at a predetermined position in a predetermined posture.

The enclosure can be formed with a conductive material to serve also as the shorting circuit.

The packaging container can also include a fastening base adapted to fasten the dye sensitized solar cell to be housed in the hollow area at a predetermined position in a predetermined posture relative to the enclosure. The fastening base can be formed with a conductive material to serve also as the shorting circuit.

The shorting circuit can include a resistor having a predetermined resistance that permits as large a current flow as possible to the extent that the dye sensitized solar cell will not be damaged.

The enclosure can house the plurality of dye sensitized solar cells.

In one mode of the present invention, the enclosure is shaped to fasten a dye sensitized solar cell at a predetermined position in a predetermined posture relative to the enclosure, and the shorting circuit shorts the two poles of the dye sensitized solar cell fastened to the enclosure.

In another mode of the present invention, the enclosure is formed with a light-shielding member and houses a dye sensitized solar cell, and the shorting circuit shorts the two poles of the dye sensitized solar cell housed in the enclosure.

The present invention allows for fastening or packaging of a solar cell, and more particularly, minimizes the deterioration of the power generation characteristic of a solar cell.

### BRIEF DESCRIPTION OF THE DRAWINGS

FIGS. 1A to 1D are diagrams illustrating examples of external circuit patterns of a dye sensitized solar cell;

FIG. 2 is a diagram illustrating an example of change in conversion efficiency of the dye sensitized solar cell with time;

FIG. 3 is a diagram describing a configuration example of a fastening base to which the present invention is applied;

FIGS. 4A and 4B are diagrams describing a configuration example of a packaging box to which the present invention is applied;

FIGS. 5A and 5B are diagrams describing another configuration example of the packaging container to which the present invention is applied; and

FIG. 6 is a diagram describing a configuration example of a solar cell manufacturing system to which the present invention is applied.

### DETAILED DESCRIPTION OF THE PREFERRED EMBODIMENTS

A description will be given below of the modes for carrying out the invention (hereinafter referred to as embodiments). It should be noted that the description will be given in the following order.

1. First embodiment (description of the change in conversion efficiency with time)
2. Second embodiment (fastening base)
3. Third embodiment (packaging container)
4. Fourth embodiment (manufacturing system)

### 1. First Embodiment

### Deterioration Due to Polarization

A description will be given first of an example of deterioration of the power generation characteristic of a dye sensitized solar cell by polarization. A comparison is made of patterns (conditions between the power collection sections) of an external circuit connected to a dye sensitized solar cell module in terms of the change in the power generation characteristic with time. The dye sensitized solar cell module has eight dye sensitized solar cell panels connected in series.

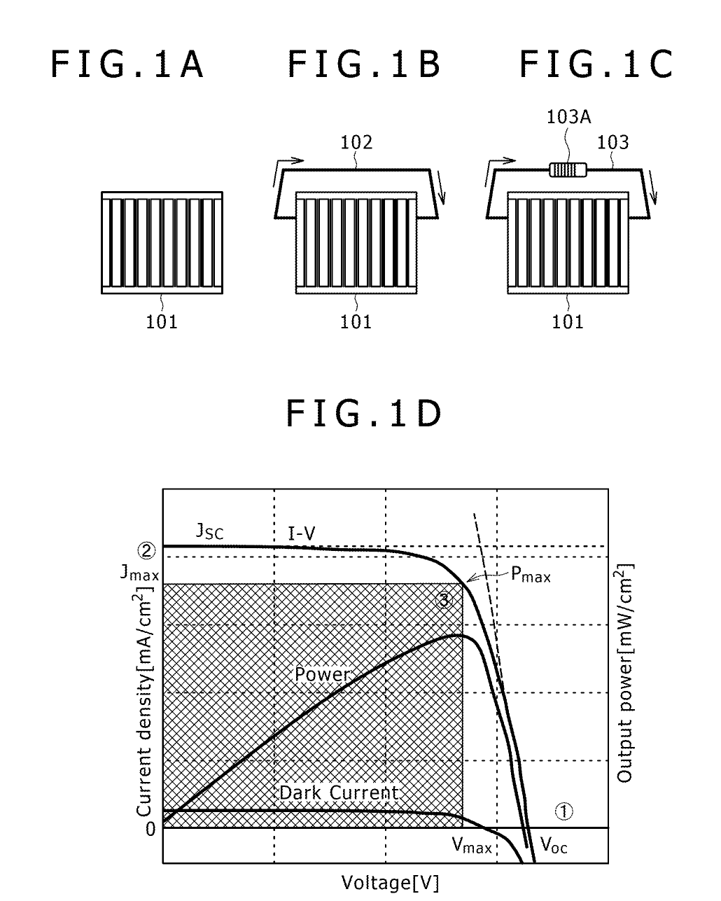

In a first condition, there is an open circuit between the power collection sections of a dye sensitized solar cell module 101 as illustrated in FIG. 1A. In this case, the resistance between the power collection sections is infinite. Therefore, the voltage-current characteristic between the power collection sections at this time corresponds to the point where the current density on the I-V characteristic curve is zero (near circled number “1”) in the graph shown in FIG. 1D.

In a second condition, the power collection sections of the dye sensitized solar cell module 101 are shorted (in a closed circuit condition) by a closed circuit 102 as illustrated in FIG. 1B. The closed circuit 102 has a zero resistance. That is, the resistance between the power collection sections is zero. Therefore, the current-voltage characteristic between the power collection sections at this time corresponds to the point where the voltage on the I-V characteristic curve is zero (near circled number “2”) in the graph shown in FIG. 1D.

In a third condition, the power collection sections of the dye sensitized solar cell module 101 are shorted (in a closed circuit condition) by a closed circuit 103 including a resistor 103A as illustrated in FIG. 1C. The resistance of the resistor 103A is set to a value that provides the maximum power. Therefore, the current-voltage characteristic between the power collection sections at this time corresponds to the point where the voltage (V) between the power collection sections and the current (J) flowing through the same sections take on the values (Vₘₐₓ, Jₘₐₓ) that deliver the maximum power (near circled number “3”) on the I-V characteristic curve in the graph shown in FIG. 1D.

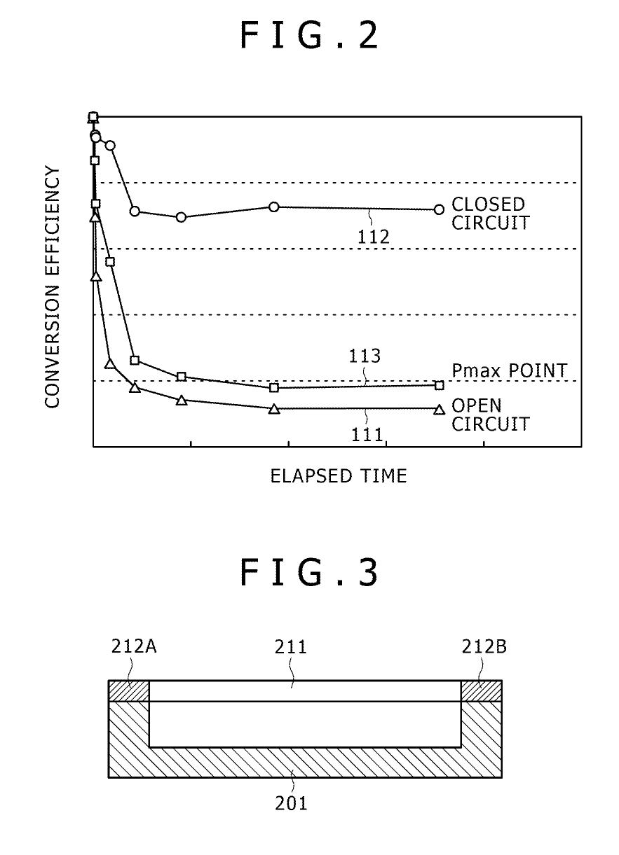

FIG. 2 illustrates an example of change in conversion efficiency of the dye sensitized solar cell module in the above three conditions with time (photo-deterioration acceleration test) when the module is left standing for extended periods in an environment where the module is irradiated with halogen light.

In the graph shown in FIG. 2, a curve 111 represents an example of change in conversion efficiency of the dye sensitized solar cell module 101 in the first condition (FIG. 1A). Further, a curve 112 represents an example of change in conversion efficiency of the dye sensitized solar cell module 101 in the second condition (FIG. 1B). Still further, a curve 113 represents an example of change in conversion efficiency of the dye sensitized solar cell module 101 in the third condition (FIG. 1C).

As illustrated in FIG. 2, the conversion efficiency of the dye sensitized solar cell module 101 tends to drop with time due to photo-deterioration basically in any of the above conditions. However, the conversion efficiency diminishes more in the first condition (open circuit) than in the other conditions.

A dye sensitized solar cell has a structure in which an electrolyte layer is provided between a porous titanium electrode carrying a sensitizing dye and its opposite electrode. In the case of a dye sensitized solar cell using an electrolyte solution that includes redox pairs (e.g., I⁻ and I₃⁻), for example, when light falls on the porous titanium electrode during power generation at daytime, the sensitizing dye absorbs the light, releasing electrons into the porous titanium electrode. At this time, the hole remaining in the sensitizing dye oxidizes the iodide ion (I⁻), changing it into a triiodide ion (I₃⁻). Further, the electrons released into the porous titanium electrode migrate to the opposite electrode by way of the circuit, reducing the triiodide ion (I₃⁻) into an iodide ion (I). As this cycle repeats itself, light energy is converted into electric energy.

However, when light is irradiated onto the dye sensitized solar cell and if the external circuit of the same cell is open-circuited, the ratio of redox pairs in the electrolyte solution becomes unbalanced, deteriorating the cell characteristic (degrading the photoelectric conversion efficiency). The possible reason for this is as follows.

The triiodide ions (I₃⁻) and iodide ions (I⁻) exist in the form of redox pairs in the electrolyte solution. However, the iodide ions (I⁻) become unevenly distributed near the porous titanium electrode, and the triiodide ions (I₃⁻) near the opposite electrode, as a result of reverse transfer of the electrons, accumulated in the porous titanium electrode, to the redox pairs, thus resulting in reduced conductivity of the electrolyte solution.

As described above, when the connection between the power collection sections of the dye sensitized solar cell module is left open, polarization occurs in a more intense manner, possibly deteriorating the power generation characteristic of the dye sensitized solar cell module more significantly.

### 2. Second Embodiment

### Fastening Base

FIG. 3 is a diagram describing a configuration example of a fastening base to which the present invention is applied. A shorting tray 201 shown in FIG. 3 has a structure in which an electrolyte solution is provided between a porous titanium electrode carrying a sensitizing dye and its opposite electrode. The shorting tray 201 is a fastening base that stably fastens a dye sensitized solar cell 211, i.e., a photoelectric conversion section adapted to convert light energy into electric energy, at a predetermined position in a predetermined posture relative to the enclosure of the shorting tray 201. The enclosure of the shorting tray 201 is shaped to fit the shape of the solar cell 211 so as to stably fasten the solar cell 211 placed thereon. The shorting tray 201 is designed primarily to protect the solar cell and used, for example, to manufacture, inspect, store and transport the solar cell 211.

Further, the enclosure of the shorting tray 201 is partially or wholly made of a conductive material so that a power collection section 212A (e.g., positive pole) and a power collection section 212B (e.g., negative pole) serving as the terminals of the two poles of the solar cell 211 placed at a predetermined position on the shorting tray 201 (fastened by the shorting tray 201) are shorted by the conductive material. That is, the shorting tray 201 has a shorting circuit adapted to short the power collection sections 212A and 212B of the fastened solar cell 211.

It should be noted that either of the power collection sections 212A and 212B may be a positive pole with the other being a negative pole so long as the two sections differ in polarity. For reasons of convenience in description, we assume that the power collection section 212A is a positive pole, and the power collection section 212B a negative pole.

Among conductive materials that can be used are metals such as steel and copper, carbon-containing plastics, aluminum evaporated plastics, and wood and paper coated with a conductive paint.

The resistance of the shorting circuit (conductive material) can be basically selected as desired. As illustrated in FIG. 2, however, the easier it is for a current to flow, the unlikelier it is that polarization will occur. It should be noted, however, that if the solar cell generates a large current through power generation, there is a risk that the cell may break down in a closed circuit condition with a zero resistance. Therefore, it is preferred that the resistance of the shorting circuit (conductive material) of the shorting tray 201 should be as small as possible to the extent that the solar cell 211 will not be damaged by the generated current (that is, as large a current as possible should flow to the extent that the solar cell 211 will not be damaged). For example, the resistance may be 1 MΩ or less so that a current of 1 mA or more flows through the solar cell 211 and the conductive material of the shorting tray 201. It should be noted that a resistor may be provided in the shorting circuit formed in the shorting tray 201 so that the above resistance can be achieved by the resistor.

This shorting circuit (conductive material) may be formed on the surface of the enclosure of the shorting tray 201. Alternatively, the shorting circuit may be formed in the enclosure. It should be noted, however, that, even in this case, the portions to be brought into contact with the power collection sections 212A and 212B need be exposed on the surface of the enclosure.

As described above, the shorting tray 201 shorts the power collection sections of the different poles of the solar cell 211 to be fastened, thus minimizing polarization in the solar cell 211 and thereby minimizing the deterioration of the power generation characteristic of the solar cell 211 which is a dye sensitized solar cell.

It should be noted that the shape of the shorting tray 201 can be selected as desired so long as the shorting tray 201 stably fastens the solar cell 211 at a predetermined position in a predetermined posture and shorts the power collection sections of the different poles of the solar cell 211. Further, the shorting tray 201 may include a resistor to control the resistance of this closed circuit. The resistance of the resistor may be fixed or variable. The resistance may be adjustable with the resistor according to the power generation output of the solar cell 211 to be fastened.

Further, the shorting tray 201 may be able to fasten the two or more solar cells 211. In this case, the power collection sections of the two poles of each of the solar cells 211 may be shorted separately. Alternatively, the power collection sections of the plurality of solar cells 211 may be shorted together.

Still further, the shorting tray 201 as a whole may be formed with a conductive material, and the enclosure of the same tray 201 may not only fasten the solar cell 211 but also serve as a shorting circuit adapted to come in contact with and short the power collection sections of the two poles of the fastened solar cell. This provides a reduced number of components of the shorting tray 201, thus facilitating the manufacture of the shorting tray 201 and ensuring reduced cost thereof.

### 3. Third Embodiment

### Packaging Box

It has been described above that the power collection sections of the different poles of a dye sensitized solar cell are shorted so as to minimize the deterioration of the power generation characteristic of the dye sensitized solar cell. However, light may be further shielded from the dye sensitized solar cell so as to suppress the power generation output of the solar cell.

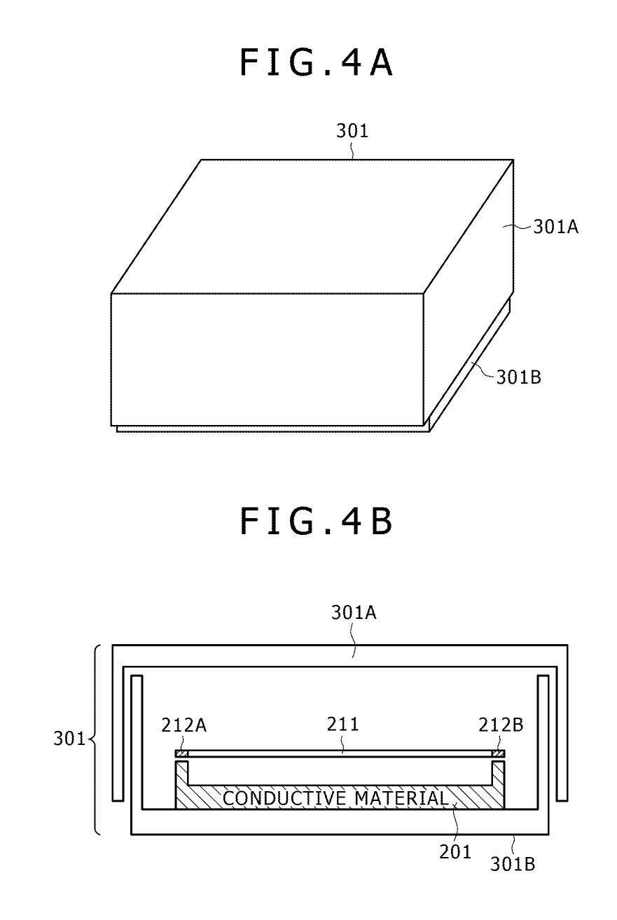

FIGS. 4A and 4B are diagrams illustrating a configuration example of a packaging container adapted to package a dye sensitized solar cell. FIG. 4A is a perspective view for describing the appearance of the packaging box.

As illustrated in FIG. 4A, a packaging box 301 is a container adapted to package a dye sensitized solar cell and includes a cover portion 301A and bottom portion 301B. As illustrated in FIG. 4A, the cover portion 301A is placed on the bottom portion 301B, thus forming the packaging box 301 in the shape of an approximate cube or parallelepiped.

FIG. 4B is a sectional view of the packaging box 301 for describing the internal configuration thereof. As illustrated in FIG. 4B, the packaging box 301 is hollow inside so that a dye sensitized solar cell can be housed. The cover portion 301A includes a top surface approximately parallel to the ground and side surfaces each of which is approximately vertical to the ground. The bottom portion 301B includes a bottom surface approximately parallel to the ground and side surfaces each of which is approximately vertical to the ground. The cover portion 301A is slightly larger than the bottom portion 301B. The cover portion 301A and bottom portion 301B are combined in such a manner that the open area of the cover portion 301A at the bottom covers the open area of the bottom portion 301B at the top, thus forming the packaging box 301.

The shorting tray 201 described above is formed on the side of the bottom surface of the bottom portion 301B inside the packaging box 301 (top side of the bottom surface). As described in the first embodiment, the shorting tray 201 fastens the solar cell 211, a dye sensitized solar cell, at a predetermined position in a predetermined posture relative to the enclosure of the shorting tray 201, with the power collection sections of the two poles shorted. It should be noted that although the solar cell 211 and shorting tray 201 are shown to be separated from each other in FIGS. 4A and 4B for convenience of description, the solar cell 211 is, in reality, fastened to the shorting tray 201 (at least the power collection sections 212A and 212B are in contact with the shorting tray 201) as illustrated in FIG. 3.

As illustrated in FIG. 4B, the solar cell 211 is fastened in place by the shorting tray 201 so that the same cell 211 is accommodated in the packaging box 301 when the cover portion 301A is closed.

The cover portion 301A and bottom portion 301B of the packaging box 301 may be made of any material including paper, wood, glass, plastic, soil, and a metal and are designed to be impermeable to light. Thanks to the cover portion 301A and bottom portion 301B that are opaque and impermeable to light, the packaging box 301 shields incident light from the internally fastened solar cell 211.

As described above, the packaging box 301 can package the solar cell 211 not only with the power collection sections of the positive and negative poles shorted but also with light shielded from the solar cell 211. This not only allows for the packaging box 301 to let the electrons, accumulated at the semiconductor electrode interface, escape out of the solar cell 211, but also minimizes dye excitation which is a supply source of electrons, thus minimizing polarization in a more intense manner and thereby minimizing the deterioration of the power generation characteristic of the solar cell 211.

It should be noted that the packaging box 301 may be in any shape so long as the enclosure thereof can block the entry of light into the solar cell 211 to be packaged and can package the solar cell 211. For example, the cover portion 301A and bottom portion 301B may be formed integrally with each other so that a surface that can be opened and closed is provided as part of the packaging box 301. Further, the packaging box 301 may be, for example, in the shape of a cone, pentagonal prism or sphere.

Further, the packaging box 301 may be able to house the two or more solar cells 211. In this case, the number of the shorting trays 201 can be selected as desired. On the other hand, the power collection sections of the two electrodes of each of the solar cells 211 may be shorted separately by the shorting tray 201. Alternatively, the power collection sections of the plurality of solar cells 211 may be shorted together by the shorting trays 201.

It should be noted that the shorting tray 201 may be formed integrally with the packaging box 301 (e.g., bottom portion 301B). Alternatively, the shorting tray 201 may be attachable to and detachable from the packaging box 301. For example, the packaging box 301 (cover portion 301A and bottom portion 301B) may be formed with a light-shielding and conductive member. At this time, the inside of the packaging box 301 may be shaped in such a manner as to fasten the solar cell 211 at a predetermined position in a predetermined posture in the packaging box 301. Further, the power collection sections of the two electrodes of the solar cell 211 may be shorted in this condition. This provides a reduced number of components of the packaging box 301, thus facilitating the manufacture of the packaging box 301 and ensuring reduced cost thereof.

It should be noted that when the power collection sections of the two electrodes of the solar cell 211 are shorted by the packaging box 301, the packaging box 301 may have a resistance that permits as large a current flow as possible through the shorted areas to the extent that the solar cell 211 will not be damaged. Further, a resistor may be provided in the shorted areas to provide the power collection sections of the two electrodes with such a resistance.

### [Packaging Material]

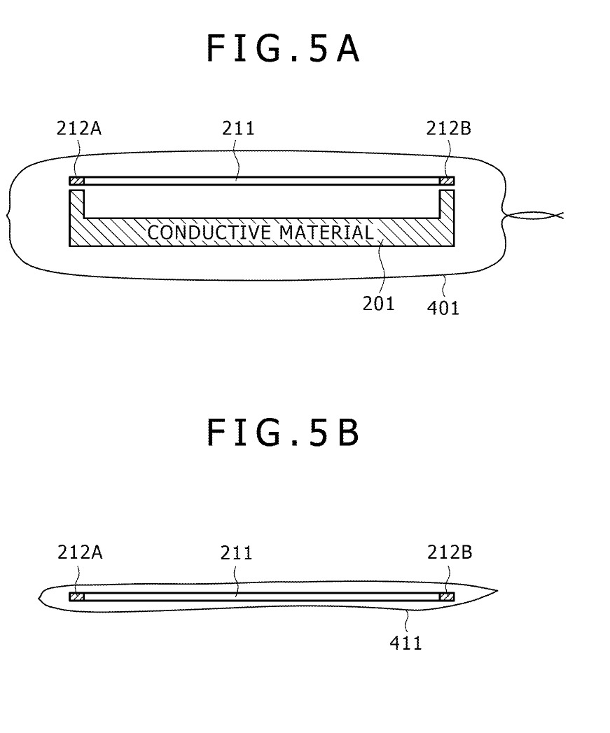

It should be noted that it is only necessary to shield light from the solar cell 211. As illustrated in FIG. 5A, for example, the solar cell 211 fastened to the shorting tray 201 may be packaged together with the shorting tray 201 as described above using a packaging material 401 made of a light-shielding member rather than the packaging box 301.

FIGS. 5A and 5B are diagrams illustrating another example of the packaging container to which the present invention is applied. In the example shown in FIG. 5A, the dye sensitized solar cell 211 is fastened in place by the shorting tray 201 made of a conductive material, with the power collection sections of the different electrodes of the solar cell 211 shorted. Further, the solar cell 211 is laminated together with the shorting tray 201 by the light-shielding packaging material 401.

As described above, the solar cell 211 can be packaged in a more compact manner by using the light-shielding packaging material 401 and the shorting tray 201 formed with a conductive material.

It should be noted that the packaging material 401 may be made of any material so long as it shields light. On the other hand, although the solar cell 211 and shorting tray 201 are shown to be separated from each other in FIG. 5A for convenience of description, the solar cell 211 is, in reality, fastened to the shorting tray 201 (at least the power collection sections 212A and 212B are in contact with the shorting tray 201) as illustrated in FIG. 3.

Further, the solar cell 211 may be packaged using a light-shielding and conductive material as illustrated in FIG. 5B. In the case of the example shown in FIG. 5B, the solar cell 211 is packaged with a conductive packaging material 411 that is both conductive and light-shielding without being fastened to the shorting tray 201. At this time, the solar cell 211 is packaged in such a manner that the conductive packaging material 411 is in contact with the power collection section 212A of the positive electrode and the power collection section 212B of the negative electrode.

The conductive packaging material 411 is formed, for example, with aluminum foil. In general, the higher the degree of flexibility of the same material 411 in terms of shape, the easier the packaging is. For example, the conductive packaging material 411 may be in a liquid or gel form. Alternatively, the same material 411 may be plastic.

As described above, using the light-shielding and conductive packaging material 411 as a packaging container provides a reduced number of components, thus facilitating the packaging of the solar cell 211 and ensuring reduced cost thereof.

It should be noted that the solar cell 211 and conductive packaging material 411 are shown to be separated from each other in FIG. 5B for convenience of description. In reality, however, the solar cell 211 is packaged so that at least the power collection sections 212A and 212B thereof are in contact with the conductive packaging material 411 as with the shorting tray 201 shown in FIG. 3.

### 4. Fourth Embodiment

### Manufacturing System of Dye Sensitized Solar Cells

Dye sensitized solar cells are capable of generating power after the injection of an electrolyte solution in the manufacturing process.

During transport in the manufacturing process, therefore, imbalance of the redox components contained in the electrolyte layer (liquid or solid such as organic solvent, ionic liquid or gel), i.e., polarization, occurs if the redox components are irradiated with light. For this reason, the manufacturing system of dye sensitized solar cells may include a mechanism adapted to shield light and short the terminals of the dye sensitized solar cells during transport thereof.

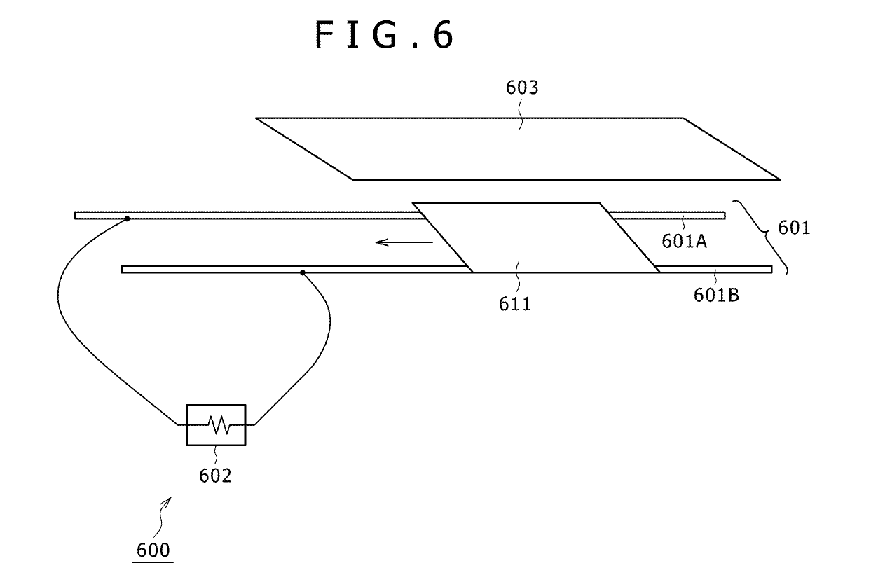

FIG. 6 is a schematic diagram for describing part of the configuration of the solar cell manufacturing system adapted to manufacture dye sensitized solar cells.

As illustrated in FIG. 6, a solar cell manufacturing system 600 includes transport rails 601 adapted to transport a dye sensitized solar cell 611 after the injection of an electrolyte solution. The transport rails 601 include rails 601A and 601B. The solar cell 611 is placed on the transport rails 601 in such a manner that the power collection sections of the two electrodes come in contact with the rail 601A or 601B. That is, the rails 601A and 601B are made of a conductive member such as metal and in contact with the power collection sections of the different electrodes.

The rails 601A and 601B are shorted via a shorting resistance 602. That is, the power collection sections of the two electrodes of the solar cell 611 are shorted via the shorting resistance 602. Although the resistance of the shorting resistance 602 can be selected as desired, it is preferred that the shorting resistance 602 should have a resistance that permits as large a current flow as possible to the extent that the solar cell will not be damaged.

This makes it possible for the solar cell manufacturing system 600 to transport the dye sensitized solar cell 611 following the injection of an electrolyte solution with the power collection sections of the two electrodes shorted. That is, the solar cell manufacturing system 600 can transport the solar cell 611 while at the same time minimizing the deterioration of its power generation characteristic.

Further, the solar cell manufacturing system 600 includes a light-shielding section 603 adapted to shield light from the solar cell 611 during transport. The light-shielding section 603 is made of a member offering high light-shielding property and formed into a shape offering high light-shielding property. For example, the light-shielding section 603 is formed to cover the solar cell 611 being transported. The transportation path of the solar cell 611 may be entirely covered. Alternatively, the solar cell 611 being transported may be partially covered. Naturally, the shape of the light-shielding section 603 can be selected as desired. The extent to which light is shielded by the light-shielding section 603 can be selected as desired so long as the light-shielding section 603 can shield light irradiated onto the solar cell 611 to a certain extent (so long as the light-shielding section 603 is substantially effective in shielding light). However, the higher the extent to which light can be shielded, the better.

As a result, the solar cell manufacturing system 600 allows for further minimization of the deterioration of the power generation characteristic of the dye sensitized solar cell 611 after the injection of an electrolyte solution.

It should be noted that the dye sensitized solar cell 611 transported by the solar cell manufacturing system 600 may be in any step so long as the step is conducted after the injection of an electrolyte solution. The same solar cell 611 transported by the solar cell manufacturing system 600 may be a completed product.

The present application contains subject matter related to that disclosed in Japanese Priority Patent Application JP 2010-128069 filed in the Japan Patent Office on Jun. 3, 2010, the entire contents of which is hereby incorporated by reference.

It should be understood by those skilled in the art that various modifications, combinations, sub-combinations and alterations may occur depending on design requirements and other factors in so far as they are within the scope of the appended claims or the equivalents thereof.

What is claimed is:

1. A fastening base comprising:
an enclosure shaped to fasten a dye sensitized solar cell at a predetermined position in a predetermined posture relative to the enclosure; and
a shorting circuit adapted to short the two poles of the dye sensitized solar cell fastened to the enclosure.

2. The fastening base of claim 1, operable to fasten the plurality of dye sensitized solar cells.

3. The fastening base of claim 1, wherein
the enclosure is formed with a conductive material to serve also as the shorting circuit.

4. The fastening base of claim 1, wherein
the shorting circuit includes a resistor having a predetermined resistance that permits as large a current flow as possible to the extent that the dye sensitized solar cell will not be damaged.

5. A packaging container comprising:
an enclosure formed with a light-shielding member and adapted to house a dye sensitized solar cell; and
a shorting circuit adapted to short the two poles of the dye sensitized solar cell housed in the enclosure.

6. The packaging container of claim 5, wherein
the enclosure has a hollow area to house the dye sensitized solar cell.

7. The packaging container of claim 6, wherein
the enclosure is shaped to fasten the dye sensitized solar cell to be housed in the hollow area at a predetermined position in a predetermined posture.

8. The packaging container of claim 7, wherein
the enclosure is formed with a conductive material to serve also as the shorting circuit.

9. The packaging container of claim 6 further comprising:
a fastening base adapted to fasten the dye sensitized solar cell to be housed in the hollow area at a predetermined position in a predetermined posture relative to the fastening base, wherein
the fastening base is formed with a conductive material to serve also as the shorting circuit.

10. The packaging container of claim 6, wherein
the shorting circuit includes a resistor having a predetermined resistance that permits as large a current flow as possible to the extent that the dye sensitized solar cell will not be damaged.

11. The packaging container of claim 5, wherein
the enclosure houses the plurality of dye sensitized solar cells.
